(19) United States
(12) Patent Application Publication
(10) Pub. No.: US 2020/0279767 A1
(43) Pub. Date: Sep. 3, 2020

(54) Silicon-Carbide-on-Insulator (SiCOI)

(71) Applicant: The Board of Trustees of the Leland Stanford Junior University, Stanford, CA (US)

(72) Inventors: Daniil M. Lukin, East Setauket, NY (US); Constantin Dory, Birenbach (DE); Jelena Vuckovic, Palo Alto, CA (US)

(21) Appl. No.: 16/805,073

(22) Filed: Feb. 28, 2020

Related U.S. Application Data
(60) Provisional application No. 62/811,939, filed on Feb. 28, 2019.

(51) Int. Cl. H01L 21/762

(52) U.S. Cl. CPC H01L 21/76251; H01L 21/02236

(57) ABSTRACT

Silicon carbide on insulator is provided by bonding bulk silicon carbide to a substrate with an oxide-oxide fusion bond, followed by thinning the bulk silicon carbide as needed.

### CROSS REFERENCE TO RELATED APPLICATIONS

This application claims priority from US Provisional Patent Application 62/811,939 filed Feb. 28, 2019, which is incorporated herein by reference.

### GOVERNMENT SPONSORSHIP

This invention was made with Government support under contract FA9550-17-1-0002 awarded by the Air Force Office of Scientific Research. The Government has certain rights in the invention.

### FIELD OF THE INVENTION

This invention relates to fabrication of silicon carbide on insulator structures.

### BACKGROUND

It is often desired to provide optoelectronically active materials in an thin-film on insulator configuration. However, providing such configurations is technologically nontrivial and highly material-dependent. For example, silicon wafers have been widely available since the 1970s, but silicon-on-insulator technology was not commercialized until the 2000s. That success with silicon has not solved the problem of providing other optoelectronically active materials in this configuration.

Silicon carbide (SiC) is one such optoelectronically active material. Here the situation is more complicated than with silicon because silicon carbide has more than 250 different polymorphs. The most commonly used SiC polymorphs are 3C-, 4H- and 6H-SiC. While e.g. 3C-SiC can be grown heteroepitaxially on Si, 4H-SiC can only be grown homoepitaxially on 4H-SiC (the same is true for many other polymorphs). Even heteroepitaxially grown 3C-SiC films on Si do not have the same pristine crystal quality as when grown homoepitaxially on 3C-SiC.

Work to date on providing SiC on insulator has considered two approaches. In the first, a thin layer of SiC is heteroepitaxially grown on a different substrate and then the SiC layer is transferred to an oxide-on-silicon substrate. In the second, bulk silicon carbide is used and an ion implant of the bulk silicon carbide is performed to define the thin layer of silicon carbide to be transferred to an oxide-on-silicon substrate. This second approach is often referred to as the smart-cut process.

However, both these approaches have substantial disadvantages. Heteroepitaxial growth of SiC can be difficult or even impossible depending on the desired polymorph, and even in cases where it is possible, the crystal quality is usually reduced. The ion implantation required by the smart cut process also reduces material quality. Accordingly, it would be an advance in the art to provide fabrication of SiC on insulator structures with improved SiC material quality.

### SUMMARY

In this work, we provide SiC on insulator using bonding, thinning and polishing techniques. The Silicon-Carbide-on-Insulator (SiCOI) that we have developed can be implemented on wafer scale and can be readily used on an industrial scale for a range of applications including electronics and photonics.

Silicon carbide has many different applications ranging from electric systems, electronic circuit elements, power electronics, LEDs, astronomy, thin filament pyrometry, heating elements, microwave photonics, photonics, quantum physics, and quantum photonics.

For example, 4H-SiC hosts color centers (point defects), which can be used as single-photon sources and quantum bits in quantum information processing (quantum computation, quantum communication, quantum transduction, quantum repeaters, photonic quantum simulators and many more). For such applications, pristine crystal quality is a necessity, as high density of defects introduces noise and reduce the optical properties of our quantum emitters to a point that they are no longer optically active. Alternative techniques, such as smart cut, leads to such poor crystal quality that we no longer see emission from quantum emitters and optical background noise is overwhelming. It can be expected that better crystal quality will also result in better performance of electronics based on SiC.

To date it is impossible to grow thin films of 4H-SiC on a material different from 4H-SiC. Thus, SiCOI through wafer bonding, thinning and polishing is the only technique which allows one to produce thin films of 4H-SiC with high yield and pristine crystal quality. This technique will also work for other polymorphs and will also improve the crystal quality of 3C-SiC thin films compared to heteroepitaxially grown 3C-SiC on Si films and films produced using Smart-Cut.

### BRIEF DESCRIPTION OF THE DRAWINGS

FIGS. 1A-D show an exemplary fabrication sequence relating to embodiments of the invention.

FIGS. 2A-H show an example of how a photonic circuit having SiC active devices connected by silicon nitride waveguides can be fabricated.

FIGS. 3A-E show fabrication and characterization results relating to exemplary embodiments of the invention.

### DETAILED DESCRIPTION

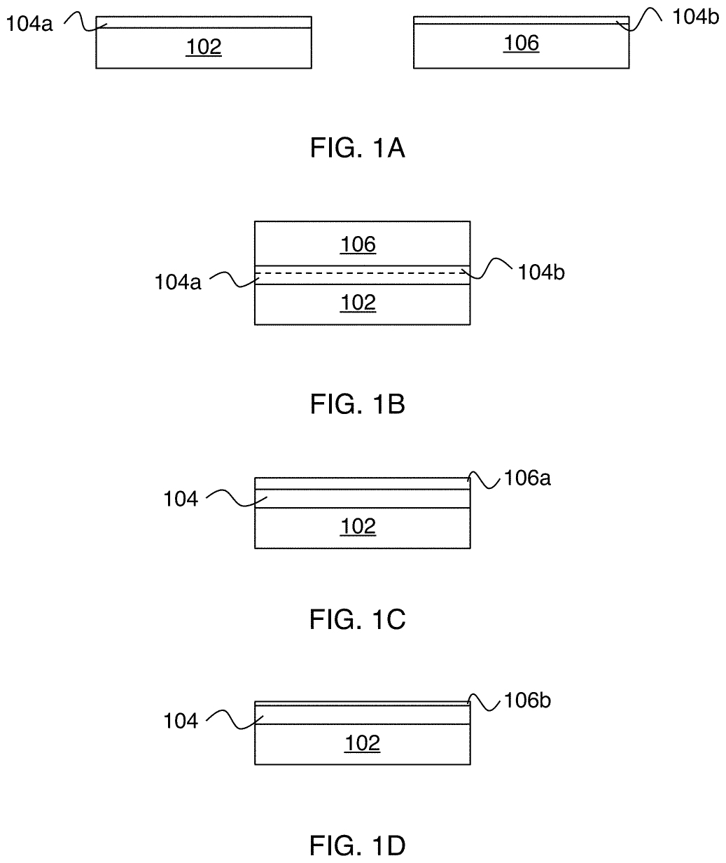

FIGS. 1A-D show an exemplary fabrication sequence. In this example, we begin with a 4-inch wafer of high purity semi-insulating 4H-SiC (106) and dice it into 10×10 mm chips. Chips are cleaned in IPA, Acetone, Piranha and HF, and undergo dry oxidation at 1000 C for 90 minutes to grow several hundred angstroms of thermal SiO₂ (104b). Separately, a SiO₂-on-Si handle wafer is prepared by thermal oxidation to provide oxide 104a on silicon substrate 102. The chips are subsequently bonded to the handle wafer at room temperature with manual pressure. The bond is strengthened by annealing at 900 C, which results in a robust SiO₂—SiO₂ fusion bond (FIG. 1B, fusion bond shown with a dashed line). Afterwards, the Si handle wafer with SiC chips on top is transferred to a wafer grinder (DAG810 from Disco Corp.) The chips are ground to a thickness of 15 μm. During the final grinding stage, a final roughness of 7 nm RMS is achieved. The wafer is then chemically-mechanically polished (POLI-400L from G&P Tech.) to a final roughness of <3 Angstrom RMS (FIG. 1C). Finally, the SiC film is further thinned down to the desired thickness via reactive ion etching (RIE) in SF₆ O₂ plasma (PlasmaTherm Versaline ICP) (FIG. 1D).

Although this example is chip-scale, not wafer scale, the same principles are applicable at wafer scale. For this purpose, we might want to switch from Si handle wafers 102 to SiC wafers 102 as on wafer scale thermal stress during and after the bonding procedure might cause a whole SiC wafer bonded to SiO₂ on Si to detach due to thermal stress. Then the process would change as follows, still with reference to FIGS. 1A-D: Substrate 102 is SiC, and because thermal oxidation of SiC is limited to about 50 nm, if a thicker oxide layer 104 is needed, then additional oxide can be deposited on the thermal oxide (e.g., with chemical vapor deposition). This deposition of extra oxide can be part of forming oxide layers 104a and/or 104b. The remaining process steps are as described above.

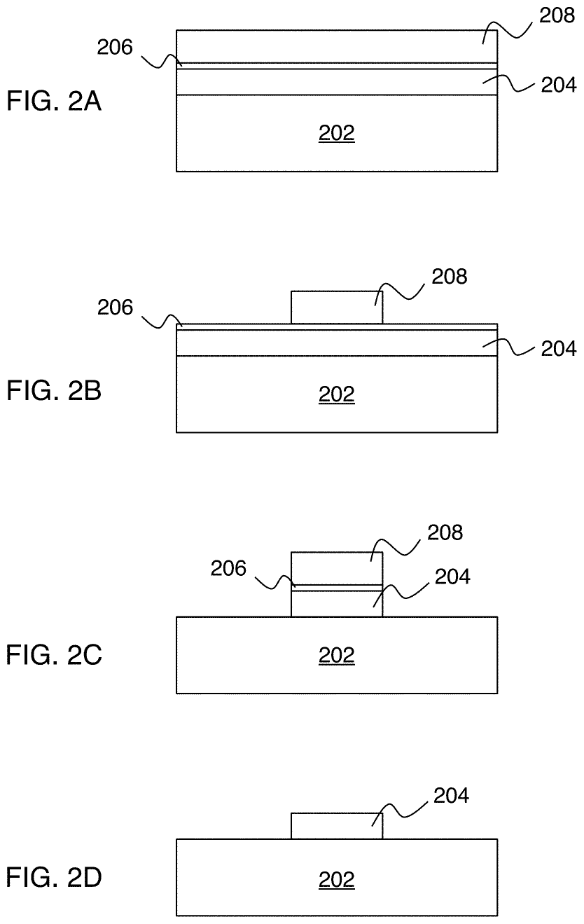

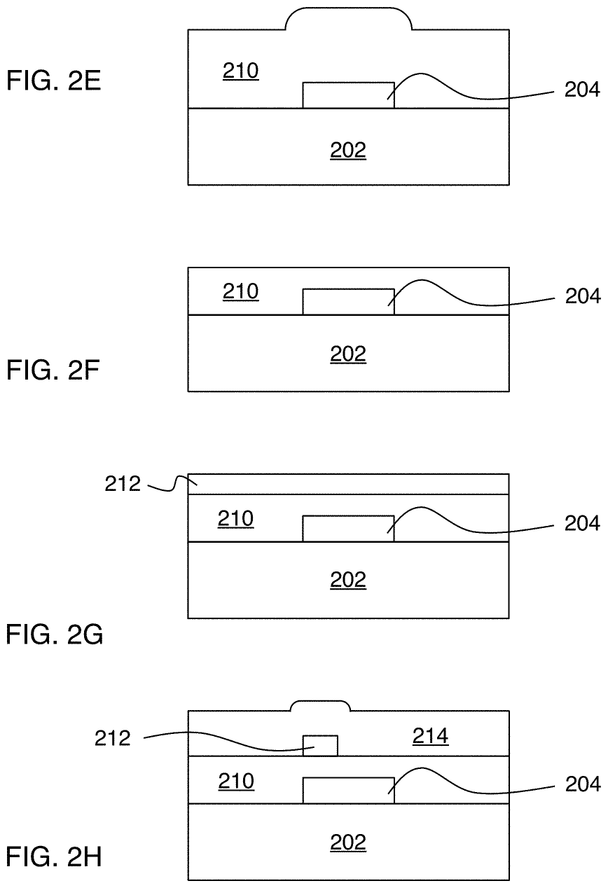

Capping of SiC devices with SiO₂ via TEOS, LPCVD or similar, typically improves performance and is done by us for devices such as waveguides or ring resonators. Furthermore, implementing a SixN_{y} platform as shown in FIGS. 2A-H, we can post select certain devices and connect them using SiₓN_{y} photonics.

The starting point of FIG. 2A shows SiC 204 disposed on oxide 202 (the substrate beneath the oxide is not shown in this sequence of figures). Here 206 is a thin (e.g., 50 nm) layer of photoresist (e.g., PMMA (Polymethyl methacrylate)), and 208 is an HSQ (Hydrogen silsesquioxane) layer. FIG. 2B shows the result of e-beam patterning layer 208. FIG. 2C shows the result of etching (e.g., with reactive ion etching) this pattern into the SiC layer 204. FIG. 2D shows the result of lifting off the HSQ layer 208. FIG. 2E shows the result of depositing oxide 210 (optionally preceded by an oxidization of the exposed surfaces of SiC 204). FIG. 2F shows the result of planarizing oxide 210. FIG. 2G shows the result of depositing silicon nitride layer 212. FIG. 2H shows the result of patterning nitride 212 and encapsulating the resulting pattern with silicon oxide 214. The resulting structure can use nitride waveguides to vertically couple to SiC active devices, thereby forming photonic circuits.

### Example

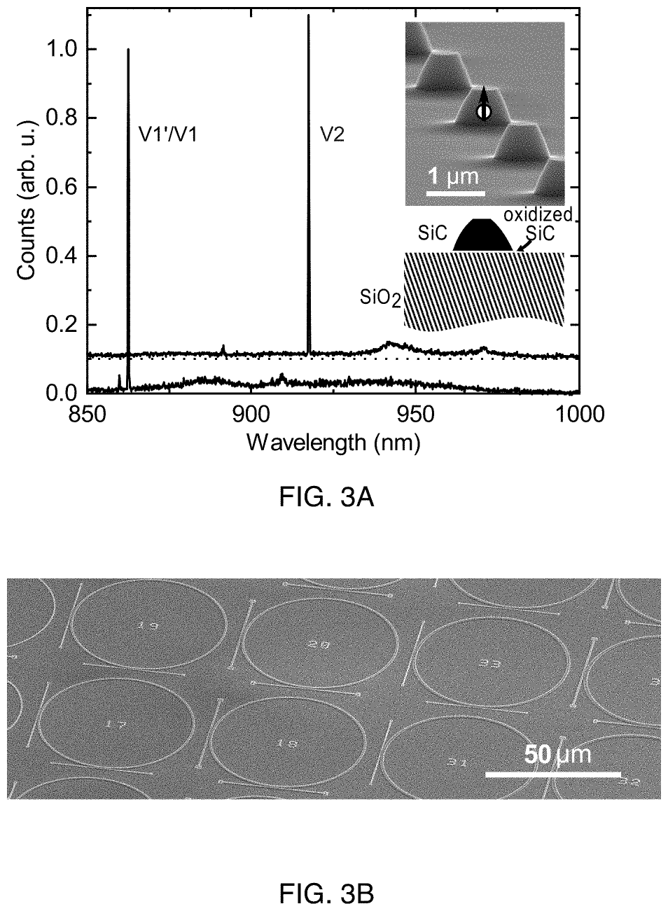

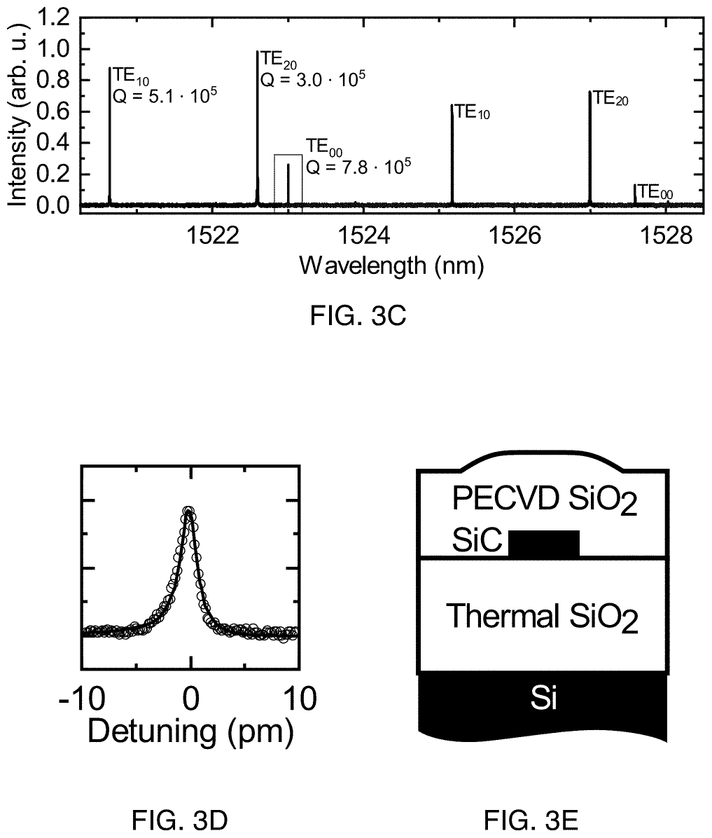

FIGS. 3A-E show exemplary fabrication and experimental results according to the above described principles.

FIG. 3A shows photoluminescence spectra of color centers in pillars fabricated in 4H-SiCOI; h-V_{Si} (V1′/V1) and k-V_{Si} (V2). These results show narrow linewidths and low-intensity phonon sidebands. The insets of FIG. 3A are an SEM image of micropillars (top) and the corresponding material stack (bottom).

FIG. 3B is an SEM image of an array of 4H-SiCOI ring resonators before SiO2 encapsulation.

FIG. 3C shows a drop-port spectrum of a ring with diameter of 55 μm, in which three TE mode families can be seen.

FIG. 3D shows a fundamental mode resonance with Q of 7.8×10⁵ (highlighted in FIG. 3C).

FIG. 3E shows a cross-section of a completed device (dimensions not to scale).

In this section, we demonstrate a low-loss 4H-silicon-carbide-on-insulator (4H-SiCOI) photonics platform using the above-described wafer bonding and thinning technique. In contrast with previous approaches, this fabrication process does not compromise the crystalline integrity of the device layer. This enabled us to show an improvement in quality factor Q by an order of magnitude over previous approaches in 4H-SiC.

Using spatially resolved photoluminescence spectroscopy, we observed single color centers in 4H-SiCOI (FIG. 3A), which had not been possible before in thin-film SiC due to compromised crystal quality. Color center characterization was performed after fabricating micropillars via reactive ion etching to improve the photon collection efficiency. The inset of FIG. 3A shows a scanning electron microscopy (SEM) image of a micropillar, while the main panel shows typical spectra of single V1 (h-lattice site) and V2 (k-lattice site) silicon vacancies (V_{Si}).

Measurements were performed at a temperature of 5K in a closed-cycle cryostat (Montana Instruments), with above-resonant excitation at 740 nm. The color center spectra show weak emission into the phonon sideband and minimal background noise, as reported in bulk 4H-SiC. By recording the fraction of micropillars that contain an emitter and estimating the micropillar volume, we arrive at an optically active defect density of 0.1 V_{Si} per μm³. In initial experiments we observed that 4H-SiC is susceptible to strong background noise at the SiC—SiO₂ fusion bond, as well as at interfaces between SiC and the plasma-enhanced chemical vapor-deposited (PECVD) oxide cladding layer. This noise overwhelmed the emission from color centers and would probably render the platform unusable for quantum applications. However, we found that a 20 nm thermal oxide layer grown on SiC before bonding or PECVD deposition fully eliminated this undesirable photoluminescence, acting as a buffer against optically active formations at the SiC interface. We thus achieved the same low background noise observed in high-purity homoepitaxial bulk crystal.

To demonstrate that our 4H-SiCOI approach also enables low-loss SiC photonics, we fabricated microring resonators (FIGS. 3B-D). We characterized their optical properties in a two-waveguide drop-port configuration using a fiber-interferometer-calibrated frequency scan, as shown in FIG. 3B. Three transverse electric (TE) mode families were observed in rings with diameter of 55 μm, width of 2.5 μm and height of 350 nm. A maximum Q factor of 7.8×10⁵ was measured for the fundamental mode, corresponding to a propagation loss of 0.5 dB cm⁻¹ (calculated using the simulated effective refractive index of the mode). This is an order of magnitude improvement over the current state of the art in 4H-SiC waveguides, where material absorption is cited as the limiting factor.

1. A method of providing a silicon carbide on insulator structure, the method comprising:
providing a silicon carbide structure;
providing a substrate structure;
forming an oxide on a surface of the silicon carbide structure to provide a first oxide layer on the silicon carbide structure;
forming an oxide on a surface of the substrate structure to provide a second oxide layer on the substrate structure;
fusion bonding the first oxide layer to the second oxide layer to provide a bonded structure; and
thinning the silicon carbide structure of the bonded structure to a predetermined thickness to provide a Silicon Carbide on Insulator structure including a thin-film silicon carbide layer;
wherein no ion implantation of the silicon carbide structure is performed prior to the fusion bonding.

2. The method of claim 1, wherein the thinning the silicon carbide structure of the bonded structure to a predetermined thickness consists of one or more steps selected from the group consisting of: grinding and polishing.

3. The method of claim 1, wherein the substrate structure comprises silicon.

4. The method of claim 1, wherein the substrate structure comprises silicon carbide.

5. The method of claim 1, wherein the thin-film silicon carbide layer comprises one or more optically active color centers.

6. The method of claim 5, wherein a density of the one or more optically active color centers is at least 0.05/μm².

7. The method of claim 1, wherein the forming an oxide on a surface of the silicon carbide structure comprises a method selected from the group consisting of: oxidizing a surface of the silicon carbide structure and depositing an oxide on the silicon carbide structure.

8. The method of claim 7, wherein the forming an oxide on a surface of the silicon carbide structure comprises oxidizing a surface of the silicon carbide structure prior to any depositing an oxide on the silicon carbide structure.

9. The method of claim 1, wherein the forming an oxide on a surface of the substrate comprises a method selected from the group consisting of: oxidizing a surface of the substrate and depositing an oxide on the substrate.

10. The method of claim 1, wherein the silicon carbide structure is a 4H silicon carbide polymorph.
